(19) United States
(12) Patent Application Publication
(10) Pub. No.: US 2009/0116199 A1
(43) Pub. Date: May 7, 2009

(54) Heat dissipating device

(75) Inventors: Chang-Chun Liu, Shenzhen (CN); Xiao-Lin Gan, Shenzhen (CN); Yu-Kuang Ho, Tu-Cheng (TW)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (Shenzhen) CO., LTD., Shenzhen City (CN); HON HAI PRECISION INDUSTRY CO., LTD., Tu-Cheng (TW)

(21) Appl. No.: 11/953,872

(22) Filed: Dec. 11, 2007

(30) Foreign Application Priority Data
Nov. 5, 2007 (CN) 200710202375.6

(51) Int. Cl. H05K 7/20

(52) U.S. Cl. 361/722

(57) ABSTRACT

A heat dissipating device includes a heat sink, and a block. The heat sink includes a base and a plurality of fins formed on the base. A bottom portion of the base forms a protrusion. The block defines a first recess and a second recess in two opposite surfaces of the block respectively. The protrusion of the heat sink engages in the first recess, and an electronic component is received in the second recess.

### BACKGROUND

1. Field of the Invention

The present invention relates to heat dissipating devices.

2. Description of related art

An equipment chassis, such as a computer chassis, usually includes a heat sink installed on an electronic component thereof for dissipating heat. Typically, the heat sink includes a base, and a plurality of fins formed on the base. A bottom of the base forms a protrusion adhered to a top surface of the electronic component, to conduct heat generated by the electronic component to the fins. Unfortunately, the base of heat sink only contacts the top surface of the electronic component and can't contact the side surfaces of the electronic component. Furthermore, detaching the heat sink from the electronic component is apt to damage the electronic component. Moreover, the heat sink can't fit an electronic component whose size and shape are different than the protrusion of the heat sink.

What is needed, therefore, is a heat dissipating device which is able to detachably fit different electronic components.

### SUMMARY

An exemplary heat dissipating device includes a heat sink, and a block. The heat sink includes a base and a plurality of fins formed on the base. A bottom portion of the base forms a protrusion. The block defines a first recess and a second recess in two opposite surfaces of the block respectively. The protrusion of the heat sink engages in the first recess, and an electronic component is received in the second recess.

Other advantages and novel features will become more apparent from the following detailed description of embodiment when taken in conjunction with the accompanying drawings, in which:

### BRIEF DESCRIPTION OF THE DRAWINGS

FIG. 1 is an exploded, isometric view of a heat dissipating device in accordance with an embodiment of the present invention;

FIG. 2 is similar to FIG. 1, but viewed from another aspect; and

FIG. 3 is an assembled view of FIG. 1.

### DETAILED DESCRIPTION

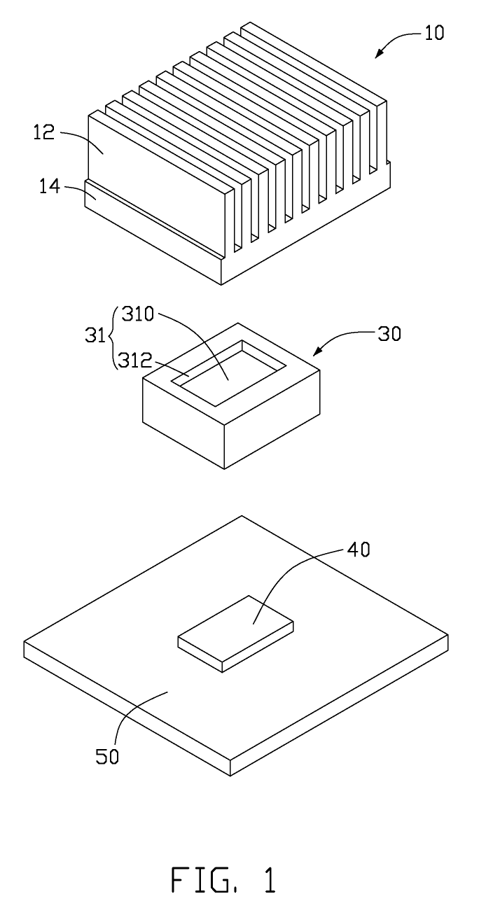

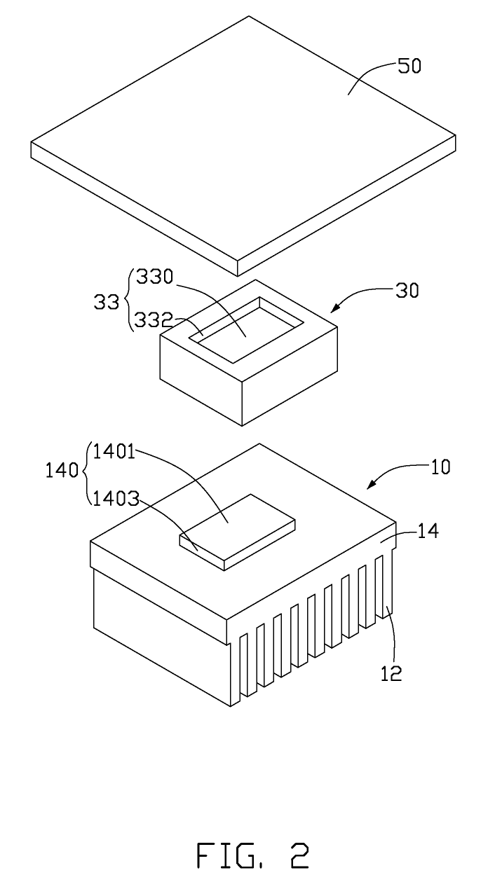

Referring to FIGS. 1 and 2, a heat dissipating device is provided in accordance with an embodiment of the present invention for an electronic component 40 on a circuit board 50. The heat dissipating device includes a heat sink 10, and a block 30.

The heat sink 10 includes a base 14, and a plurality of fins 12 formed on the base 14. A protrusion 140 extends from a middle of a bottom portion of the base 14. The protrusion 140 includes a bottom surface 1401 and four lateral surfaces 1403.

The block 30 is made of material having good heat conductivity. The block 30 includes a first recess 31 defined in a middle of a top surface of the block 30, and a second recess 33 defined in a middle of a bottom surface of the block 30. The shape and size of the first recess 31 is the same as the protrusion 140 of the heat sink 10. The first recess 31 includes a first end wall 310, and four sidewalls 312. The shape and size of the second recess 33 is the same as the electronic component 40 on the circuit board 50. The second recess 33 includes a second end wall 330, and four sidewalls 332.

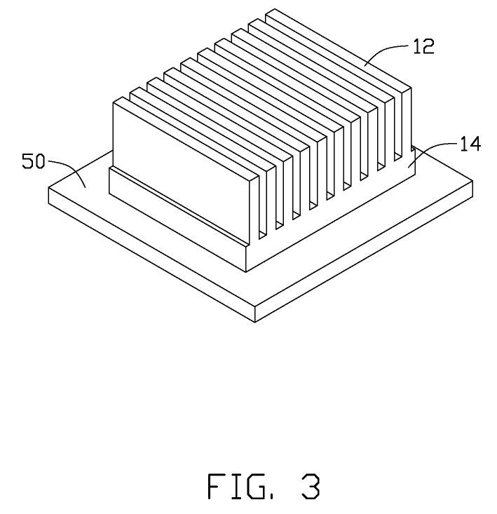

Referring further to FIG. 3, in assembly, the second end wall 330, and the sidewalls 332 of the second recess 33 are coated with heat conductive paste. The block 30 is placed on the electronic component 40, with a top surface and four lateral surfaces of the electronic component 40 engaging with and adhered to the second end wall 330 and the sidewalls 332 of the second recess 33 respectively. The top surface of the block 30, with the first end wall 310, and the sidewalls 312 of the first recess 31 are coated with heat conductive paste. The heat sink 10 is placed on the block 30, with the bottom portion of the base 14 of the heat sink 10 adhered to the top surface of the block 30, and the bottom surface 1401 and the lateral surfaces 1403 of the protrusion 140 of the base 14 engaging with and adhered to the first end wall 310 and the sidewalls 312 of the first recess 31 respectively.

When the electronic component 40 on the circuit board 50 is in use, heat generated by the electronic component 40 is conducted to the protrusion 140 of the base 14 of the heat sink 10 via the block 30. Thereafter, the heat is conducted to the fins 12 of the heat sink 10 and then is dissipated by a fan mounted on the fins 12.

To fit a different electronic component, the block 30 may be replaced with another block defining a second recess having the same shape or size with that of the different electronic component. Should the heat sink 10 need to be removed, it can be detached from the first recess 31 of the block 30, without risking damage to the electronic component 40.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A heat dissipating device for an electronic component, the heat dissipating device comprising:
a heat sink comprising a base and a plurality of fins formed on the base, a bottom portion of the base forming a protrusion; and
a block for being placed on the electronic component, the block defining a first recess and a second recess in two opposite surfaces of the block respectively, the protrusion of the heat sink engaging in the first recess, and the second recess adapted for engaging with the electronic component.

2. The heat dissipating device as claimed in claim 1, wherein the block is made of material having high heat conductivity.

3. The heat dissipating device as claimed in claim 1, wherein inside surfaces of the first and second recesses are coated with heat conductive paste.

4. The heat dissipating device as claimed in claim 1, wherein one of the surfaces defining the first recess of the block is coated with heat conductive paste.

5. A heat dissipating device mounted on an electronic component, the heat dissipating device comprising:
a heat sink comprising a base, a bottom portion of the base forming a protrusion; and;
a block defining a first recess and a second recess in two different surfaces of the block respectively, the protrusion of the heat sink received in the first recess, and the electronic component received in the second recess.

6. The heat dissipating device as claimed in claim 5, wherein the block is made of material having high heat conductivity.

7. The heat dissipating device as claimed in claim 5, wherein the block comprises a top surface and a bottom surface opposite to the top surface, the first and second recesses are defined in the top and bottom surfaces respectively.

8. The heat dissipating device as claimed in claim 7, wherein heat conductive paste is spread between the top surface and the bottom portion of the base of the heat sink.

9. The heat dissipating device as claimed in claim 5, wherein inside surfaces of the first and second recesses are coated with heat conductive paste.
